(19) United States
(12) Patent Application Publication
(10) Pub. No.: US 2015/0049486 A1
(43) Pub. Date: Feb. 19, 2015

(54) LED ILLUMINATION MODULE

(71) Applicant: Seoul Semiconductor Co., Ltd., Ansan-si (KR)

(72) Inventors: Jung Hwa Jung, Ansan-si (KR); Eun Ju Kim, Ansan-si (KR); Seoung Ho Jung, Ansan-si (KR)

(73) Assignee: Seoul Semiconductor Co., Ltd, Ansan-si (KR)

(21) Appl. No.: 14/385,231

(22) PCT Filed: Mar. 14, 2013
(86) PCT No.: PCT/KR2013/002050

§ 371 Date: Sep. 15, 2014

(30) Foreign Application Priority Data
Mar. 14, 2012 (KR) 10-2012-0026275

(51) Int. Cl. F21V 13/02; H01L 33/52; H01L 33/50; F21K 99/00; F21V 29/00; F21V 17/12

(52) U.S. Cl. CPC F21V 13/02; F21V 29/2212; F21V 17/12; H01L 33/50; F21K 9/50; H01L 33/52; F21Y 2101/02
USPC 362/260

(57) ABSTRACT

Provided is a light emitting diode (LED) illumination module. The LED illumination module includes a fluorescent substance plate mounted to be capable of being attached to and detached from an opening formed in a top surface of a heat sink. Also, the LED illumination module includes a lens that covers the opening of the heat sink and is mounted to be capable of being attached to and detached from the heat sink.

### CROSS-REFERENCE TO RELATED APPLICATIONS

This application is the National Stage of International Application No. PCT/KR2013/002050, filed on Mar. 14, 2013, and claims priority from and the benefit of Korean Patent Application No. 10-2012-0026275, filed on Mar. 14, 2012, which are hereby incorporated by reference for all purposes as if fully set forth herein.

### BACKGROUND

1. Field

The present invention relates to an illumination module, and more particularly, to a light emitting diode (LED) illumination module mounted integrally with a heat sink.

2. Discussion of the Background

Since light emitting diodes (LEDs) have many advantages, such as environmental friendliness, a long lifespan, low power consumption, and high luminous efficiency, the application range of LEDs has gradually expanded with recent developments of semiconductor technology. In particular, with the recent commercialization of high-luminance white LEDs, various attempts to adopt the high-luminance white LEDs as illuminators have continued.

FIG. 1 is a cross-sectional view of a conventional LED package.

The conventional LED package may include a package main body 1 on which lead frames 2 and 3 are disposed, the package main body 1 having an opening 4, an LED chip 5 mounted on the package main body 1, a bonding wire 6 connected to the LED chip 5, an encapsulation unit 7 covering the LED chip 5 and the bonding wire 6 within the opening 4, and a lens 8 capable of adjusting an orientation angle of emitted light.

The encapsulation unit 7 may include a fluorescent substance 9 configured to convert a wavelength of some light emitted from the LED chip 5. In general, the encapsulation unit 7 may be formed by molding an encapsulant containing the fluorescent substance 9 in the opening 4.

However, in the above-described case, since the fluorescent substance 9 is integrally formed with the LED package along with the encapsulation unit 7, the LED package itself should be attached and detached to change the color of emitted light. Also, the fluorescent substance 9 is liable to be degraded due to heat generated by the LED chip 5.

Meanwhile, although an orientation angle of light emitted by an LED is about 120°, an orientation angle larger than 120° is required to use the LED for an illuminator. Accordingly, an additional secondary lens is needed to obtain an orientation angle of about 180° or more, and there was a burden of preparing an additional support unit configured to locate the lens at a sufficient height from the ground.

### SUMMARY

Accordingly, the present invention is directed to a light emitting diode (LED) illumination module in which a fluorescent substance plate and a lens may be mounted to be capable of being attached to and detached from a heat sink.

One aspect of the present invention provides a light emitting diode (LED) illumination module. The LED illumination module includes a heat sink including an opening formed in a top surface of the heat sink and a recess unit formed in a bottom surface of the opening, the recess unit having a smaller width than the opening, an LED package including at least one LED chip mounted within the recess unit, at least one fluorescent substance plate mounted to be capable of being attached to and detached from the opening, and a lens covering the opening and mounted on the heat sink.

The LED chip may be spaced a predetermined distance apart from the fluorescent substance plate mounted within the opening.

The lens may be mounted to be capable of being attached to and detached from the heat sink.

According to the present invention, since a fluorescent substance plate is mounted to be attached to and detached from a heat sink, the color of emitted light can be easily changed as needed. Also, since the fluorescent substance plate is mounted a predetermined distance apart from an LED chip, the loss of optical efficiency can be minimized. In addition, degradation of a fluorescent substance due to heat generated by the LED chip can be prevented.

Furthermore, since the heat sink itself can serve to support a lens, no additional support unit is required to increase the efficiency of a fabrication process. Moreover, since the lens is mounted to be capable of being attached to and detached from the heat sink, the lens may be exchanged with a different one to obtain various light orientation angles.

Aspects of the present invention should not be limited by the above description, and other unmentioned aspects will be clearly understood by one of ordinary skill in the art from exemplary embodiments described herein.

### BRIEF DESCRIPTION OF THE DRAWINGS

FIG. 1 is a cross-sectional view of a conventional light emitting diode (LED) package.

FIG. 2 is a cross-sectional view of an LED illumination module according to an exemplary embodiment of the present invention.

FIG. 3 is a cross-sectional view of an LED illumination module to and from which a fluorescent substance plate and a lens are externally attached and detached according to an exemplary embodiment of the present invention.

FIG. 4 is a cross-sectional view of an LED illumination module to and from which a fluorescent substance plate and a lens are externally attached and detached according to another exemplary embodiment of the present invention.

FIG. 5 is a cross-sectional view of an LED illumination module according to another exemplary embodiment of the present invention.

FIG. 6 is a cross-sectional view of an LED illumination module to and from which a lens is externally attached and detached according to another exemplary embodiment of the present invention.

FIG. 7 is a cross-sectional view of an LED illumination module according to another exemplary embodiment of the present invention.

FIG. 8 is a cross-sectional view of an LED illumination module according to another exemplary embodiment of the present invention.

### DETAILED DESCRIPTION OF THE ILLUSTRATED EMBODIMENTS

Hereinafter, exemplary embodiments of the present invention will be described in detail. It should be understood, however, that there is no intent to limit the invention to the particular forms disclosed. On the contrary, the invention is to cover all modifications, equivalents, and alternatives falling within the spirit and scope of the claims.

It will be understood that when a layer is referred to as being “on” another layer or substrate, it can be directly on the other layer or substrate or intervening layers may also be present. Terms that describe spatial relationships, such as “beneath,” “below,” “lower,” “above,” “upper” and the like, may be used herein for ease of description to describe one element or feature's relationship to another element(s) or feature(s) as illustrated in the figures. It will be understood that such terms are intended to encompass different orientations of the device in use or operation in addition to the orientation(s) depicted in the figures. For example, if the device in the figures is turned over, elements described as “below” or “beneath” other elements or features would then be oriented “above” the other elements or features. Thus, the term “below” can encompass both an orientation of above and below. The orientation of the device may be changed in other ways (e.g., rotated 90 degrees or some other angle) and spatial relationships described herein should be interpreted within the context of the changed orientation.

In the drawings, the thicknesses of layers and regions may be exaggerated for clarity. Like reference numerals refer to like elements throughout.

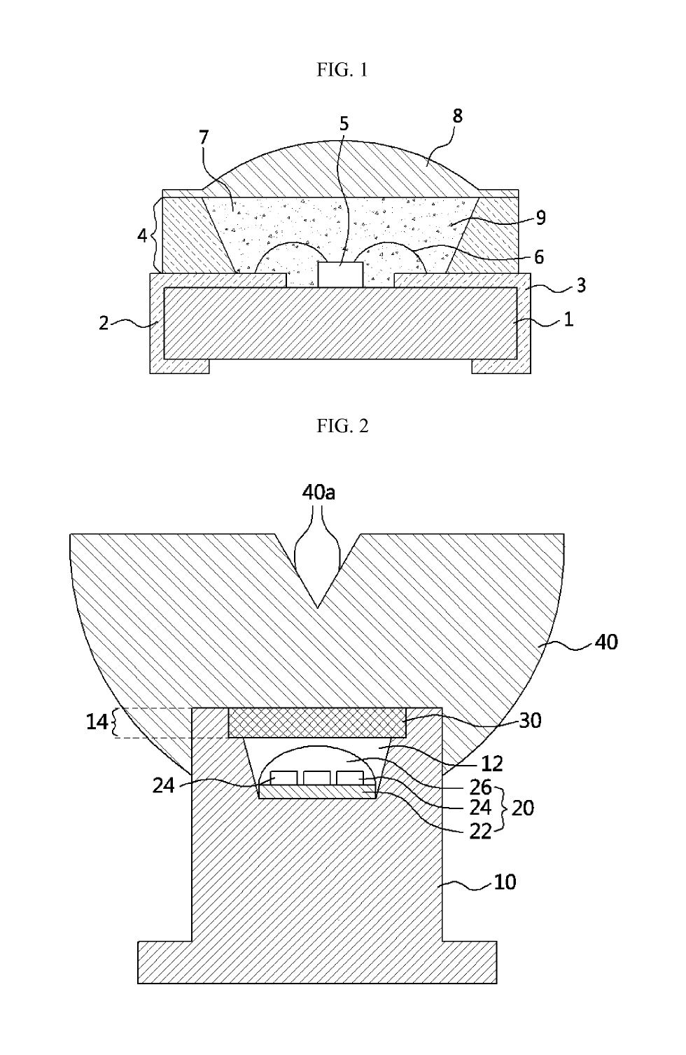

FIG. 2 is a cross-sectional view of a light emitting diode (LED) illumination module according to an exemplary embodiment of the present invention.

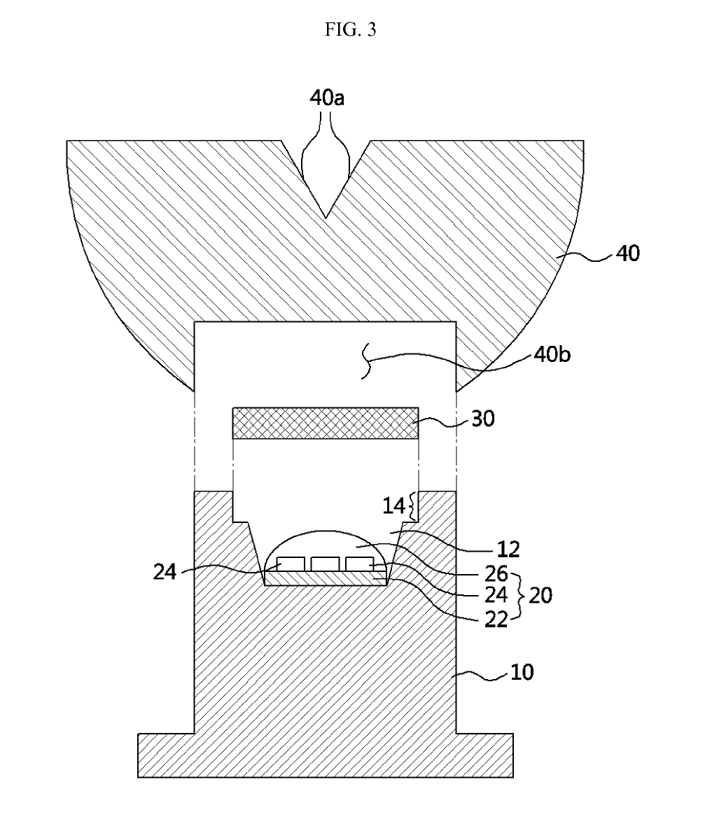

FIG. 3 is a cross-sectional view of an LED illumination module, to and from which a fluorescent substance plate and a lens are externally attached and detached, according to an exemplary embodiment of the present invention.

Referring to FIGS. 2 and 3, a heat sink 10 may include a recess unit 12 in which an LED package 20 may be mounted, and an opening 14, which may extend onto the recess unit 12. A fluorescent substance plate 30 may be mounted in the recess unit 12.

The heat sink 10 may serve to externally emit heat generated by the LED package 20. The heat sink 10 may be formed of a metal having good thermal conductivity.

In addition, the heat sink 10 serves to support a lens 40 formed to cover the opening 14 of the heat sink 10. In this case, the heat sink 10 preferably has such a height as to sufficiently space the lens 40 from the ground. Accordingly, an additional unit for supporting the lens 40 may not be used, and an orientation angle of light may increase.

The LED package 20 may be mounted in the recess unit 12. Although FIGS. 2 and 3 illustrate that a package 20 including a plurality of LED chips 24 is mounted in the recess unit 12, the present invention is not limited thereto. In some cases, a plurality of LED packages may be mounted, or a package including one LED chip may be mounted.

The LED package 20 may include a circuit substrate 22 having an electrode pattern, an LED chip 24 formed on the circuit substrate 22, and an encapsulation unit 26 configured to encapsulate the LED chip 24. In another case, the electrode pattern may be directly formed on the heat sink without the circuit substrate 22. Although not shown in the drawings, the LED chip 24 may be electrically connected to the electrode pattern through a bonding wire.

The LED chip 24 may be a light source configured to emit light having a predetermined orientation angle due to an applied current. The LED chip 24 may have a horizontal, vertical, or flip-chip structure. At least one LED chip 24 may be mounted as needed. Light emitted by the LED chip 24 may be ultraviolet (UV) light or blue light and mixed with light emitted from a fluorescent substance to embody white light.

A sidewall of the recess unit 12 may have a predetermined slope in consideration of an orientation angle of light of the LED chip 24. In this case, when the heat sink 10 is formed of a metal (e.g., aluminum (Al)) having high light reflectance, an additional reflection surface may not be formed on the sidewall of the recess unit 12.

However, in another case, an additional reflection surface may be formed on the sidewall of the recess unit 12. In an example, the reflection surface may be formed by coating a light reflection material having a high reflection rate. For example, the light reflection material may be titanium oxide (TiO₂), silicon oxide (SiO₂), or zinc oxide (ZnO). However, the present invention is not limited thereto.

The encapsulation unit 26 may encapsulate the LED chip 24 and include a light-transmitting resin including at least one selected out of a silicone resin, an epoxy resin, an acrylic resin, or a urethane resin. However, the present invention is not limited thereto.

The opening 14 is formed in a top surface of the heat sink 10. The opening 14 may form a predetermined partition over the recess unit 12. In this case, the opening 14 may have a greater width than the width of the recess unit 12. As a result, the later-described fluorescent substance plate 30 may cover the entire surface of the LED package 20 mounted in the recess unit 12. Also, the opening 14 may be formed to have such a width as to provide an area into which the fluorescent substance plate 30 may be tightly inserted. The present invention is not limited thereto, and the width of the opening 14 measured in a major-axis direction may be equal to or different from the width of the opening 14 measured in a minor-axis direction. Also, an additional element or structure for mounting the fluorescent substance plate 30 not in the opening 14 but on the recess unit 12 may be prepared. The shapes and positions of the opening 14 and the recess unit 12 may be changed.

The fluorescent substance plate 30 may be mounted within the opening 14. In this case, the fluorescent substance plate 30 may be spaced a predetermined distance apart from the LED chip 24. For example, the distance between the LED chip 24 and the fluorescent substance plate 30 may be defined by the depth of the recess unit 12.

The fluorescent substance plate 30 may be a ceramic plate. The ceramic plate may be formed by arranging fluorescent substance particles and heating the fluorescent substance particles under a high pressure until the surfaces of the fluorescent substance particles begin to soften and melt. In this case, the sintered fluorescent substance particles may be of different kinds. Since a material (e.g., a resin) having a low thermal conductivity is excluded from the ceramic plate, heat generated by a fluorescent substance may be efficiently emitted to improve heat dissipation performance.

Furthermore, the fluorescent substance plate 30 may be formed by coating a fluorescent substance on the surface of a resin film. In this case, respective surfaces of the fluorescent substance plate 30 may be coated with different kinds of fluorescent substances. However, the present invention is not limited thereto, and a fluorescent substance may be included in the resin film. The resin film may be a thermosetting resin film having transparency. For example, the thermosetting resin may be selected from the group consisting of an epoxy resin, a silicone resin, polycarbonate (PC), and polymethylmethacrylate (PMMA).

For example, the fluorescent substance plate 30 may include a red fluorescent substance, a blue fluorescent substance, or a yellow fluorescent substance. When the LED chip 24 is a UV LED chip, the red fluorescent substance, the blue fluorescent substance, and the yellow fluorescent substance may be included in the fluorescent substance plate 30 to embody white light. When the LED chip 24 is a blue LED chip, the yellow fluorescent substance may be included in the fluorescent substance plate 30 to embody white light.

The fluorescent substance plate 30 may be inserted into the opening 14. Various kinds of fluorescent substance plates 30 may be exchanged and mounted as needed. Thus, various combinations of colors may be made so that the color of emitted light can be easily changed.

The lens 40 is mounted to cover the opening 14 of the heat sink 10. The lens 40 functions to protect the LED package 20 from the external environment and adjust an orientation angle of light. The lens 40 may have various shapes and be exchanged as needed. Accordingly, various light orientation angles may be obtained.

The lens 40 may be mounted to be capable of being attached and detached. In an example, a groove unit 40b corresponding to an outer circumferential shape of the heat sink 10 may be prepared in a lower portion of the lens 40. Accordingly, the lens 40 may be mounted to cover at least an upper portion of the heat sink 10. However, the present invention is not limited thereto, and the mounting of the lens 40 according to other embodiments will be described later.

The lens 40 may be a plastic lens fabricated by injection-molding a polymer, such as an epoxy resin, an acrylic resin, PMMA, PC, or cyclo-olefin polymer (COP). However, the present invention is not limited thereto.

Although the lens 40 may have various shapes as mentioned above, when the lens 40 has corners, color separation may occur due to a prismatic effect caused at the corners of the lens 40. In this case, the corners of the lens 40 may be mechanically or chemically processed to form roughness and induce diffused reflection so that light emitted by the lens 40 can be softened.

Furthermore, the lens 40 may have at least one total reflection surface to control a direction in which light is emitted. In an example, a central portion of the lens 40 may have a total reflection surface 40a having a V sectional shape. However, the present invention is not limited thereto, and the total reflection surface 40a may have any shape having such a slope as to totally reflect light that is emitted from the LED chip 24 and incident on the total reflection surface 40a.

Since the light emitted from the LED chip 24 is mainly emitted in a vertical direction, a relatively large quantity of light is concentrated on the central portion of the lens 40. In this case, when the central portion of the lens 40 has the total reflection surface 40a having the V sectional shape, light incident on the central portion of the lens 40 may be totally reflected, refracted at a refraction surface of the rounded lens 40, and emitted toward the ground. Accordingly, the LED illumination module according to one embodiment of the present invention may widen an orientation angle of emitted light and be effectively used for an illuminator configured to illuminate a wide ambient region.

The lens 40 may contain a light diffusion material. For example, the light diffusion material may be a material, such as SiO₂, Al₂O₃, Zr₂O₃, Y₂O₃, TiO₂, B₂O₃, or CaCO₃. Thus, a light diffusion effect may be increased within the lens 40, thereby softening emitted light.

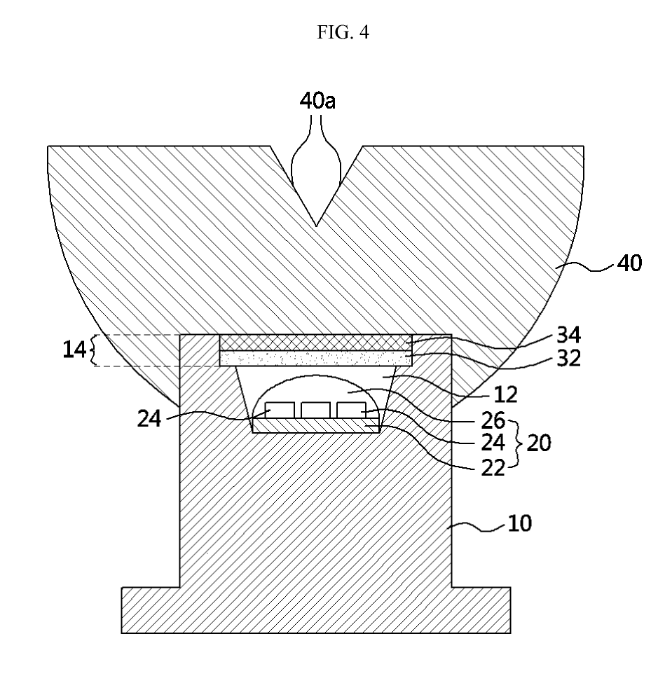

FIG. 4 is a cross-sectional view of an LED illumination module according to another exemplary embodiment of the present invention.

Referring to FIG. 4, a plurality of fluorescent substance plates 32 and 34 may be mounted within an opening 14 of a heat sink 10.

The plurality of fluorescent substance plates 32 and 34 may be sequentially stacked and mounted within the opening 14. A first fluorescent substance plate 32 disposed close to an LED chip 24 may contain a fluorescent substance having a longer wavelength than a second fluorescent substance plate 34 mounted on the first fluorescent substance plate 32.

In an example, when the LED chip 24 is a blue LED chip, the first fluorescent substance plate 32 may contain a red fluorescent substance, and the second fluorescent substance plate 34 may contain a yellow fluorescent substance. A first emission spectrum of blue light emitted by the LED chip 24 is initially radiated to and partially absorbed by the first fluorescent substance plate 32, and a wavelength-converted second emission spectrum may be emitted. Although the second emission spectrum is radiated to the second fluorescent substance plate 34, the second emission spectrum is not absorbed but transmitted. Meanwhile, part of the first emission spectrum transmitted through the first fluorescent substance plate 32 is radiated to and partially absorbed by the second fluorescent substance plate 34, and a wavelength-converted third emission spectrum is emitted. Accordingly, a first blue spectrum, a second red spectrum, and a third yellow spectrum may be mixed to embody white light having good color rendition.

Although FIG. 4 shows an example in which two fluorescent substance plates 32 and 34 are mounted, the present invention is not limited thereto. A plurality of different kinds of fluorescent substance plates may be mounted within the opening 14 as needed.

Since other components are the same as those of FIG. 2, a repeated description thereof is omitted.

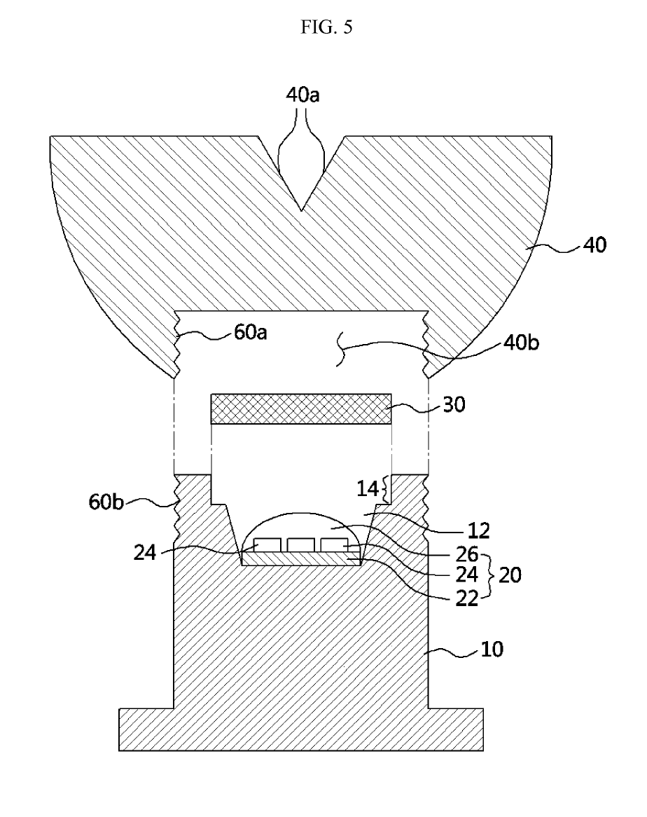

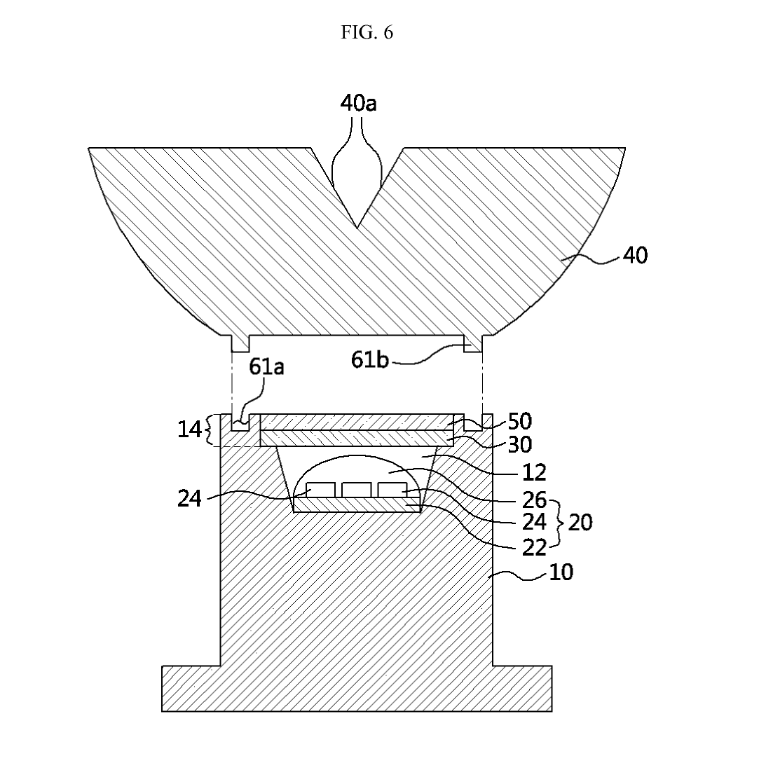

FIG. 5 is a cross-sectional view of an LED illumination module to and from which a fluorescent substance plate and a lens are externally attached and detached according to another exemplary embodiment of the present invention.

Referring to FIG. 5, the lens 40 may be mounted to be capable of being attached and detached. In an example, a groove unit 40b corresponding to an outer circumferential shape of the heat sink 10 may be prepared in a lower portion of the lens 40. Accordingly, the lens 40 may be mounted to cover at least an upper region of the heat sink 10.

In this case, the lens 40 may be spirally combined with an upper portion of the heat sink 10. That is, a screw protrusion 60a may be formed on an inner circumferential edge of the lower portion of the lens 40, and a screw groove 60b is formed in an outer circumferential edge of the upper portion of the heat sink 10 so that the screw protrusion 60a and the screw groove 60b can be spirally combined with each other. The screw protrusion 60a may be integrally formed with the lens 40, and the screw groove 60b may be integrally formed with the heat sink 10. However, the present invention is not limited thereto. In another case, a screw groove 60b may be formed in an inner circumferential edge of the lower portion of the lens 40, and a screw protrusion 60a may be formed on an outer circumferential edge of the upper portion of the heat sink 10 so that the screw groove 60b and the screw protrusion 60a can be spirally combined with each other.

Since other components are the same as those of FIG. 2, a repeated description thereof is omitted.

FIG. 6 is a cross-sectional view of an LED illumination module to and from which a lens is attached and detached, according to another exemplary embodiment of the present invention.

Referring to FIG. 6, a fluorescent substance plate 30 and an optical plate 50 may be mounted in an opening 14 of a heat sink 10.

The optical plate 50 may serve to control light emitted from an LED chip 24. In an example, the optical plate 50 may be a light diffuser plate. The light diffuser plate may be disposed on the fluorescent substance plate 30 and diffuse light transmitted through the fluorescent substance plate 30. For example, the light diffuser plate may be formed by sintering particles formed of a material, such as SiO₂, Al₂O₃, Zr₂O₃, Y₂O₃, TiO₂, B₂O₃, or CaCO₃, at a high temperature under a high pressure.

In another example, the optical plate 50 may be a dichroic filter. The dichroic filter may selectively transmit or cut off light having a specific wavelength. The dichroic filter may be interposed between the LED chip 24 and the fluorescent substance plate 30. The dichroic filter may transmit light emitted from the LED chip 24 and reflect light emitted from the fluorescent substance plate 30.

Accordingly, since backward scattered light, out of the light emitted from the fluorescent substance plate 30, is cut off by the dichroic filter, damage due to heat absorbed by the LED chip 24 may be prevented. However, the present invention is not limited thereto, and dichroic filters may be disposed among a plurality of fluorescent substance plates. The dichroic filter may have a structure in which at least two materials having a different refractive index are alternately stacked on the glass or resin film having a high transmission rate.

The lens 40 may be mounted to cover the opening 14 of the heat sink 10. In an example, an insertion groove 61a may be formed in a top surface of the heat sink 10 and an insertion protrusion 61b may be formed on a bottom surface of the lens 40 so that the insertion groove 61a and the insertion protrusion 61b may be inserted into and combined with each other. The insertion groove 61a may be integrally formed with the heat sink 10, and the insertion protrusion 61b may be integrally formed with the lens 40. Shapes of the insertion groove 61a and the insertion protrusion 61b may be variously changed. However, the present invention is not limited thereto. An insertion groove 61a may be formed in any one of the bottom surface of the lens 40 and the top surface of the heat sink 10 and an insertion protrusion 61b may be formed on the other one thereof, so the insertion groove 61a and the insertion protrusion 61b may be inserted into and combined with each other.

Since other components are the same as those of FIG. 2, a repeated description thereof is omitted.

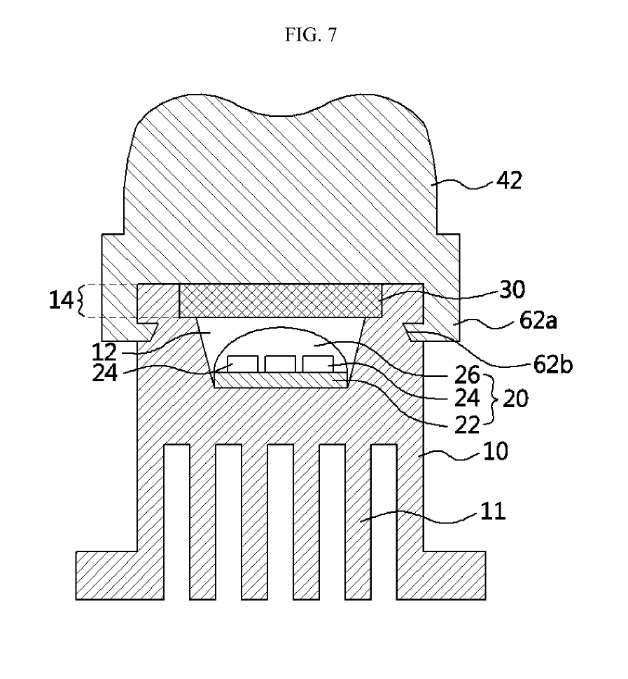

FIG. 7 is a cross-sectional view of an LED illumination module according to another exemplary embodiment of the present invention.

Referring to FIG. 7, a lens 42 may have a concave central portion, and a lateral portion extending from the central portion of the lens 42 may have a convex shape. Since light emitted from the LED chip 24 is mainly emitted in a vertical direction, the quantity of light is relatively concentrated on the central portion of the lens 42. In this case, while light is being transmitted through the central portion of the lens 42, the light may be refracted in a lateral direction of the lens 42 to increase the quantity of light emitted from the the lateral portion of the lens 42.

The lens 42 may cover an opening 14 of a heat sink 10 and be mounted to be capable of being attached and detached. In an example, a groove unit corresponding to an outer circumferential shape of the heat sink may be prepared in a lower portion of the lens 42 and simultaneously, the lens 42 may include an insertion protrusion 62a. An insertion groove 62b having a shape corresponding to the insertion protrusion 62a may be prepared in a sidewall of the heat sink 10. Due to the above-described structure, the lens 42 may be mounted on the heat sink 10 and coupled with the heat sink 10 more strongly than in the manner in which the lens 40 shown in FIG. 2 is mounted. However, the present invention is not limited thereto, and a lens may be mounted using various coupling units.

A plurality of heat radiation fins 11 may be prepared in a lower portion of the heat sink 10 to increase a heat dissipation area and improve heat dissipation performance. However, the present invention is not limited thereto, and the heat sink 10 may have any shape for increasing the heat dissipation area.

Since other components are the same as those of FIG. 2, a repeated description thereof is omitted.

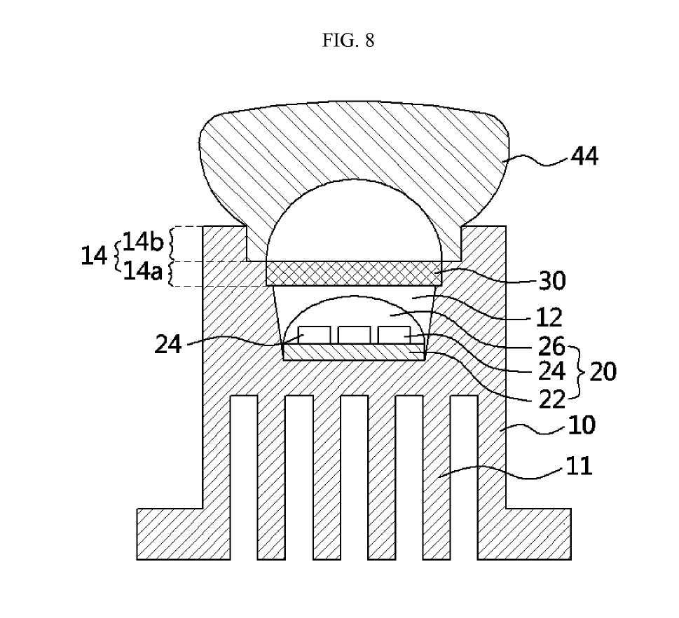

FIG. 8 is a cross-sectional view of an LED illumination module according to another exemplary embodiment of the present invention.

Referring to FIG. 8, a portion of a lens 44 may be inserted into an upper end of the opening 14. For example, the opening 14 may be stepped. The opening 14 may include a first stepped portion 14a and a second stepped portion 14b disposed on the first stepped portion 14a.

A fluorescent substance plate 30 may be mounted in the first stepped portion 14a, and a portion of the lens 44 may be mounted in the second stepped portion 14b.

In an example, the lens 44 may have an arched structure. A semicircular refraction surface may be prepared not only on a top surface of the lens 44 having the arched structure but also on a bottom surface thereof. Accordingly, an orientation angle of light transmitted through the lens 44 and emitted outward may further increase.

Since other components are the same as those of FIG. 2, a repeated description thereof is omitted.

While the invention has been shown and described with reference to certain exemplary embodiments thereof, it will be understood by those skilled in the art that various changes in form and details may be made therein without departing from the spirit and scope of the invention as defined by the appended claims.

1. A light emitting diode (LED) illumination module, comprising:
a heat sink comprising an opening in a top surface of the heat sink and a recess unit formed in a bottom surface of the opening, the recess unit having a smaller width than the opening;
an LED package comprising an LED chip disposed within the recess unit;
a fluorescent substance plate detachably disposed in the opening; and
a lens covering the opening and disposed on the heat sink.

2. The LED illumination module of claim 1, wherein the LED chip is spaced from the fluorescent substance plate.

3. The LED illumination module of claim 2, wherein the distance between the LED chip and the fluorescent substance plate is defined by a depth of the recess unit.

4. The LED illumination module of claim 1, further comprising an optical plate detachably disposed in the opening.

5. The LED illumination module of claim 4, wherein the optical plate comprises a light diffuser plate or a dichroic filter.

6. The LED illumination module of claim 1, wherein the lens is detachably disposed on the heat sink.

7. The LED illumination module of claim 6, wherein:
a groove unit corresponding to an outer circumferential shape of the heat sink is formed in a lower portion of the lens; and
the heat sink is disposed in the groove unit.

8. The LED illumination module of claim 6, wherein the lens is spirally connected with the heat sink.

9. The LED illumination module of claim 6, wherein:
an insertion groove is formed in a bottom surface of the lens or a top surface of the heat sink;
an insertion protrusion is formed in the bottom surface of the lens or the top surface of the heat sink, opposite to the insertion groove; and
the insertion groove and the insertion protrusion are detachably connected.

10. The LED illumination module of claim 1, wherein a central portion of the lens comprises a total reflection surface having a V sectional shape.

11. The LED illumination module of claim 1, wherein the LED package comprises:
an LED chip disposed on a circuit substrate disposed in the recess unit; and
an encapsulation unit covering the LED chip.

12. The LED illumination module of claim 8, wherein:
a screw groove corresponding to an inner circumferential edge of the lens is formed on an upper portion of the heat sink;
a screw protrusion corresponding to an outer circumferential edge of the heat sink is formed on a lower portion of the lens; and
the screw groove and the screw protrusion are detachably connected.
